(19) United States
(12) Patent Application Publication
(10) Pub. No.: US 2026/0007050 A1
(43) Pub. Date: Jan. 1, 2026

(54) DISPLAY DEVICE AND ELECTRONIC DEVICE

(71) Applicant: Samsung Display Co., LTD., Yongin-si (KR)

(72) Inventors: JISEONG YANG, Yongin-si (KR); CHEOL SHIN, Yongin-si (KR); SONGEE LEE, Yongin-si (KR); SI-WAN JEON, Yongin-si (KR); SEOK-JOON HONG, Yongin-si (KR)

(73) Assignee: Samsung Display Co., LTD., Yongin-si (KR)

(21) Appl. No.: 19/018,699

(22) Filed: Jan. 13, 2025

(30) Foreign Application Priority Data
Jun. 28, 2024 (KR) 10-2024-0085255

(51) Int. Cl. H10K 59/80; H10H 29/37; H10H 29/85; H10H 29/851; H10H 29/856; H10K 59/122; H10K 59/38; H10K 102/00

(52) U.S. Cl. CPC H10K 59/878; H10H 29/37; H10H 29/8512; H10H 29/8517; H10H 29/856; H10K 59/122; H10K 59/38; H10K 2102/331

(57) ABSTRACT

A display device includes a lower substrate, an upper substrate and a filling layer. The lower substrate includes a light-emitting diode layer, a color control layer and a spacer. The light-emitting diode layer includes light-emitting diodes. The color control layer includes a bank including an opening and a color control portion disposed in the opening. The spacer is disposed on the bank. The color control portion includes a quantum dot. The upper substrate is disposed on the lower substrate and includes color filters. The filling layer is disposed between the lower substrate and the upper substrate to adhere the lower substrate with the upper substrate. The filling layer has a higher refractive index than a refractive index of the spacer.

### CROSS-REFERENCE TO RELATED APPLICATION(S)

This application claims priority to and benefits of Korean Patent Application No. 10-2024-0085255 under 35 U.S.C. § 119, filed on Jun. 28, 2024, in the Korean Intellectual Property Office, the entire contents of which are incorporated herein by reference.

### BACKGROUND

### 1. Technical Field

The disclosure relates to a display device, and to a display device including a spacer having an optical effect.

### 2. Description of the Related Art

Display devices are used in various electronic devices, such as televisions, monitors, automotive displays, tablet computers, smartphones, and gaming consoles. Various techniques are being researched and developed to improve the performance of these display devices.

Among these techniques studied, display devices utilizing quantum dots exhibit excellent color reproduction, high color purity, high brightness characteristics, wide viewing angles and long lifespans. Accordingly, the markets for display devices utilizing quantum dots are increasingly growing, and a large number of research are being conducted.

In the art, in case that display devices using quantum dots are made to have a high resolution, some of the light emitted by the quantum dots could not exit the screen. As a result, it was found that some of the light that could not exit the screen was absorbed within the display device, leading to a reduction in optical efficiency, and some of the light was reflected within the display device, potentially affecting other pixels.

Therefore, there is a growing need for addressing these issues by improving the display devices utilizing quantum dots.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An object of the disclosure is to provide a display device with excellent optical efficiency and color reproduction.

A display device in accordance with an embodiment of the disclosure may include a lower substrate, an upper substrate and a filling layer.

The lower substrate may include a light-emitting diode layer, a color control layer and a spacer. The light-emitting diode layer may include a plurality of light-emitting diodes. The color control layer may include a bank including an opening and a first color control portion disposed in the opening. The spacer may be disposed on the bank.

The upper substrate may be disposed on the lower substrate and may include a plurality of color filters.

The filling layer may be disposed between the lower substrate and the upper substrate and may adhere the lower substrate with the upper substrate and have a higher refractive index than a refractive index of the spacer.

In an embodiment, the plurality of color filters may include a first color filter. A portion of the light emitted from the first color control portion may be reflected by the spacer. Another portion of the reflected light may pass through the first color filter and may be emitted outside of the display device.

In an embodiment, another portion of the light emitted from the first color control portion may pass through the spacer. The passed light may not be emitted outside of the display device.

In an embodiment, the color control layer may further include a second color control portion and a third color control portion.

The first color control portion may emit light having a first wavelength. The second color control portion may emit light having a second wavelength different from the first wavelength and may be adjacent to the first color control portion and spaced apart from the first color control portion by a first distance. The third color control portion may emit light having a third wavelength different from the first wavelength and the second wavelength and may be adjacent to the second color control portion and spaced apart from the second color control portion by a second distance.

A smaller value of the first distance and the second distance may be defined as an adjacent distance. A portion of the bank that is separated from the first color control portion to the adjacent distance may be defined as a first adjacent area. A portion of the bank that is separated from the second color control portion to the adjacent distance may be defined as a second adjacent area. A portion of the bank that is separated from the third color control portion to the adjacent distance may be defined as a third adjacent area. The spacer may be disposed on at least one of the first adjacent area, the second adjacent area and the third adjacent area.

In an embodiment, an area of the bank in which the first adjacent area and the second adjacent area overlap each other may be defined as a first overlap area. An area of the bank in which the second adjacent area and the third adjacent area overlap each other may be defined as a second overlap area. The spacer may be disposed on at least one of the first overlap area and the second overlap area.

In an embodiment, each of the first color control portion, the second color control portion and the third color control portion may extend in a selectable direction. The first color control portion, the second color control portion and the third color control portion may each be disposed in a direction intersecting the selectable direction. The spacer may extend in the selectable direction.

In an embodiment, a distance between the spacer and the upper substrate may be greater than or equal to about 0.3 μm and less than or equal to about 2 μm.

In an embodiment, the spacer may have a shape that encloses each of the first color control portion, the second color control portion and the third color control portion in plan view.

In an embodiment, each of the first color control portion, the second color control portion and the third color control portion may extend in a selectable direction. The spacer may include a first sub-spacer and a second sub-spacer.

The first sub-spacer may be disposed between the first color control portion and the second color control portion in plan view and extend in the selectable direction. The second sub-spacer may be disposed between the second color control portion and the third color control portion in plan view, may extend in the selectable direction, and may be spaced apart from the second sub-spacer.

In an embodiment, each of the first color control portion, the second color control portion and the third color control portion may extend in a selectable direction, and the spacer may include a first sub-spacer and a second sub-spacer.

The first sub-spacer may be disposed between the first color control portion and the second color control portion in plan view and extend in a selectable direction. The second sub-spacer may have a shape that encloses the third color control section in plan view.

In an embodiment, the spacer may include a plurality of sub-spacers, each having a substantially circular or substantially oval shape.

In an embodiment, a plurality of first sub-spacers among the plurality of sub-spacers may be disposed on the first adjacent area. A plurality of second sub-spacers among the plurality of sub-spacers may be disposed on the third adjacent area. A number of the plurality second sub-spacers may be greater than a number of the plurality of first sub-spacers.

In an embodiment, the refractive index of the spacer may be about 1.3 to about 1.4. The refractive index of the filling layer may be about 1.45 to about 1.55.

A display device in accordance with an embodiment may include a light-emitting diode layer, a bank, a plurality of color control portions, a spacer, a filling layer and a plurality of color filters.

The light-emitting diode layer may emit light. The bank may be disposed on the light-emitting diode layer and may include a plurality of partition walls. One of the plurality of color control portions may include a quantum dot, and each of the plurality of color control portions may be disposed between the plurality of partition walls. The spacer may include a plurality of sub-spacers disposed, respectively, on the plurality of partition walls and may have a first refractive index. The filling layer may be disposed on the spacer and the plurality of color control portions and may have a second refractive index, which is greater than the first refractive index. The plurality of color filters may be disposed on the filling layer.

In the embodiment, a portion of the light emitted from the plurality of color control sections may be reflected by the spacer. Another portion of the reflected light may pass through the plurality of color filters and may be emitted outside of the display device.

In the embodiment, each of the plurality of sub-spacers may include a portion with a decreasing cross-sectional area away from the bank.

In the embodiment, a distance between the spacer and the plurality of color filters may be greater than or equal to about 0.3 μm and less than or equal to about 2 μm.

In the embodiment, each of the plurality of color control portions may extend in a selectable direction. The plurality of color control portions may be disposed in a direction intersecting the selectable direction. Each of the plurality of sub-spacers may include a portion extending in the selectable direction.

In the embodiment, each of the plurality of spacers may have a shape that encloses at least one of the plurality of color control portions in plan view.

In the embodiment, each of the plurality of color control portions may extend in a selectable direction. The plurality of sub-spacers may include a first sub-spacer and a second sub-spacer.

The first sub-spacer may extend in the selectable direction. The second sub-spacer may extend in the selectable direction and may be spaced apart from the first sub-spacer.

With these and other embodiments, it is possible to provide a display device having excellent optical efficiency and color reproduction.

### BRIEF DESCRIPTION OF THE DRAWINGS

These and/or other features will become apparent and more readily appreciated from the following description of the embodiments, taken in conjunction with the accompanying drawings in which:

FIG. 1 is a schematic perspective view showing a display device according to an embodiment;

FIG. 2 is an exploded view of the display device according to an embodiment;

FIG. 3 is a magnified view of the pixel area illustrated in FIG. 2;

FIG. 4 is an illustration of a partial schematic cross-section taken along line I-I′ of FIG. 3;

FIG. 5 separately illustrates the bottom substrate from the schematic cross-section shown in FIG. 4;

FIG. 6 separately illustrates the top substrate from the schematic cross-section shown in FIG. 4;

FIG. 7 is a magnified view of the schematic cross-section shown in FIG. 4, further illustrating the path of light, and with some elements omitted;

FIG. 8 is an illustration of the pixel area of the bottom substrate according to an embodiment;

FIG. 9 is a magnified schematic cross-sectional view of the pixel area according to an embodiment;

FIG. 10 is a magnified schematic cross-sectional view of the pixel area according to an embodiment;

FIG. 11 is a magnified schematic cross-sectional view of the pixel area according to an embodiment;

FIG. 12 is an illustration of the pixel area of the bottom substrate according to an embodiment;

FIG. 13 is an illustration of the pixel area of the bottom substrate according to an embodiment;

FIG. 14 is an illustration of the pixel area of the bottom substrate according to an embodiment;

FIG. 15 is an illustration of the pixel area of the bottom substrate according to an embodiment;

FIG. 16 is an illustration of the pixel area of the bottom substrate according to a different embodiment;

FIG. 17 is an illustration of the pixel area of the bottom substrate according to a different embodiment;

FIG. 18 is an illustration of the pixel area of the bottom substrate according to a different embodiment;

FIG. 19 is an illustration of the pixel area of the bottom substrate according to a different embodiment;

FIG. 20 is an illustration of the pixel area of the bottom substrate according to a different embodiment;

FIG. 21 is an illustration of a partial schematic cross-sectional view of the top substrate according to an embodiment; and

FIG. 22 is an illustration of a partial schematic cross-section taken along line I-I′ of FIG. 3.

### DETAILED DESCRIPTION OF THE EMBODIMENTS

References will now be made in detail to embodiments, of which examples are illustrated in the accompanying drawings, where like reference numerals refer to like elements throughout. The embodiments may have a variety of forms and permutations, but the disclosure shall by no means be construed as being limited to the described embodiments. Rather, the disclosure shall be construed to encompass all forms, permutations, equivalents and substitutes covered by the technical ideas and scope of the disclosure. Accordingly, embodiments are described below, by referring to the figures, to explain features of the disclosure.

In the accompanying drawings, the thicknesses, ratios, and dimensions of the elements may not be to exact scale and may have been exaggerated for the benefit of effective explanation of the technical features associated with these elements.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

When an element is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. On the other hand, if one element is described to be “directly disposed on,” “directly placed on,” “directly arranged on,” “directly connected to,” or “directly coupled to” another element, it shall be construed that there is no other element disposed therebetween.

Moreover, relative terms, such as “below,” “beneath,” “lower,” “bottom,” “above,” “over,” “upper,” “top,” etc., may be used herein to describe one element's relationship to another element as illustrated in the accompanying figures. It shall be understood that relative terms are intended to encompass different orientations of the device in addition to the orientation depicted in the accompanying figures. For example, if the device in one of the figures is turned over, elements described as being on the “lower” side of the other elements would then be oriented on “upper” sides of the other elements. The term “lower” can therefore encompass an orientation of both “lower” and “upper,” depending on the particular orientation of the figure. Similarly, if the device in one of the figures is turned over, elements described as “below” or “beneath” other elements would then be oriented “above” the other elements. The term “below” or “beneath” can therefore encompass an orientation of both above and below.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Terms such as “first” and “second” may be used in describing various elements, but the above elements shall not be restricted to the above terms. The above terms may be used only to distinguish one element from the other. For instance, the first element may be named the second element, and vice versa, without departing the scope of claims of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

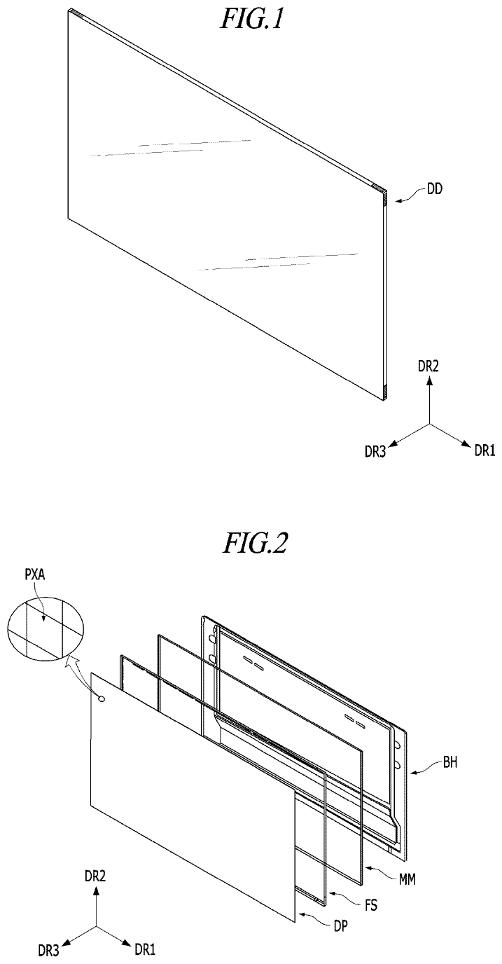

FIG. 1 is a schematic perspective view showing a display device DD according to an embodiment. FIG. 2 is an exploded view of the display device DD according to an embodiment.

As illustrated in FIGS. 1 and 2, first to third directions DR1, DR2, and DR3 may be defined. The first direction DR1 and the second direction DR2 may be directions defined on a plane of the display device DD shown in FIG. 1 and may intersect with each other. The third direction DR3 may be in a direction of thickness of the display device DD shown in FIG. 1.

Referring to FIG. 1, the display device DD may be a device configured to display a screen on its front face. The display device DD may be included in the electronic device. For example, the display device DD may be a monitor or a television. Nevertheless, the shape and use of the display device DD is not limited to these examples. For instance, the front face of the display device DD may have a circular shape or a polygonal shape. Moreover, the display device DD may not be flat but curved in a particular direction. Moreover, the display device DD may be, for example, a laptop computer, a billboard, a smartphone, a tablet PC, an automotive display or a wearable device.

Referring to FIG. 2, the display device DD may include a display panel DP, a front chassis FS, a middle mold MM and a back housing BH. The front display panel DP may have a plurality of pixel areas PXA defined therein. Moreover, the display device DD may be assembled by having the display panel DP disposed in an opening portion defined in the front face of the front chassis FS, coupling (or connecting) the display panel DP with the middle mold MM and coupling the middle mold MM with the back housing BH.

The display panel DP is a portion of the display device DD that displays a screen and may be exposed to the front face of the display device DD. Moreover, the display panel DP may have the plurality of pixel areas PXA defined therein to allow a screen to be displayed in the display panel DP by activating each of the pixel areas PXA.

The front chassis FS may have the opening portion defined in the front face to allow the display panel DP to be disposed in the opening portion. Accordingly, the front face of the display panel DP may not be obscured by other elements, thereby allowing the bezel of the display device DD to be narrower.

A portion of the middle mold MM may be coupled (or connected) to the back face, and another portion of the middle mold MM may be coupled to the front chassis FS. Accordingly, the display panel DP disposed in the front face of the front chassis FS may be fixed.

The back housing BH may be coupled with the middle mold MM. Moreover, the back housing BH may be provided in a plate shape to protect the display panel DP from, for example, an external impact. Moreover, the back housing BH may include an exhaust port to discharge internal heat to the outside.

Moreover, the plurality pixel areas PXA defined in the display panel DP may be arranged (or disposed) with a particular array on the display panel DP. For example, the plurality pixel areas PXA may be repeatedly arranged in the first direction DR1, and the plurality pixel areas PXA repeatedly arranged in the first direction DR1 may be also repeatedly arranged in the second direction DR2. As a result, the plurality pixel areas PXA may be arranged in a lattice shape.

The plurality pixel areas PXA may be arranged in a different array from the above-described fashion. For instance, the plurality pixel areas PXA may be arranged in a lattice shape that is slanted by about 45 degrees in a direction. Moreover, each of the plurality pixel areas PXA may display a different color on the display panel DP.

Moreover, the display device DD may further include other elements that are not illustrated in the drawings. For example, the display device DD may further include an AD board (not shown). As such, inputted analog signals may be converted to digital signals and transferred to the display panel DP. Moreover, the display device DD may further include a speaker (not shown). Accordingly, acoustic information may be additionally transferred.

Hereinafter, the pixel areas PXA of the disclosure will be described in more detail with reference to the drawings.

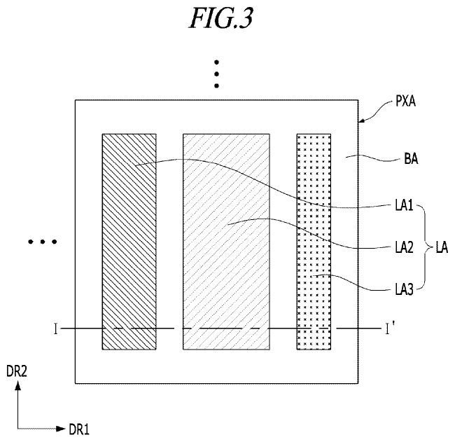

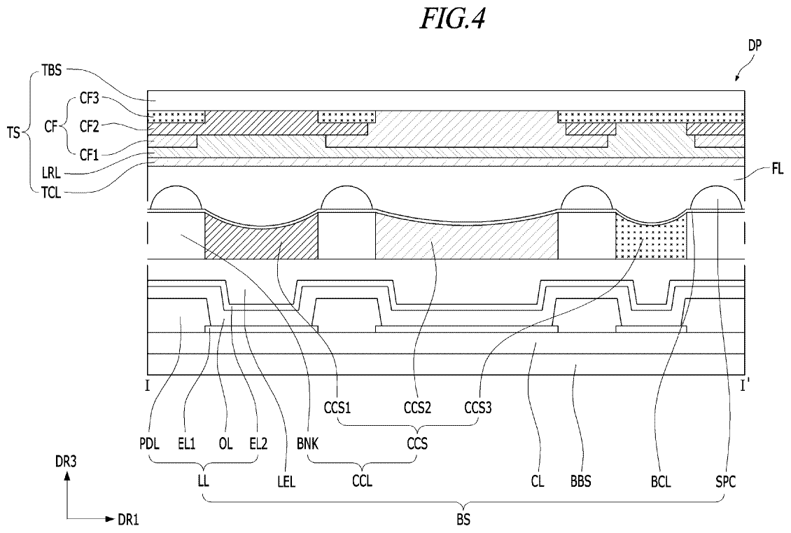

FIG. 3 is a magnified view of the pixel area PXA illustrated in FIG. 2, and FIG. 4 is an illustration of a partial schematic cross-section taken along line I-I′ of FIG. 3.

Referring to FIG. 3, the pixel area PXA of the disclosure may include a light-emitting area LA, which may be configured to emit light, and a light-blocking area BA, which does not emit light. The light-emitting area LA may emit light in the pixel area PXA. The light-emitting area LA may include a first light-emitting area LA1, a second light-emitting area LA2 and a third light-emitting area LA3.

The first light-emitting area LA1 may be configured to emit light having a first wavelength, for example, red light with a peak wavelength in the range of about 610 nm to about 650 nm. The second light-emitting area LA2 may be configured to emit light having a second wavelength different from the first wavelength, for example, green light with a peak wavelength in the range of about 510 nm to about 550 nm. The third light-emitting area LA3 may be configured to emit light having a third wavelength different from both the first and second wavelengths, for example, blue light with a peak wavelength in the range of about 400 nm to about 480 nm. Furthermore, the brightness of the first light-emitting area LA1, the second light-emitting area LA2, and the third light-emitting area LA3 may be adjusted to control the color of the light displayed in the pixel area PXA.

Moreover, the shapes of the first light-emitting area LA1, the second light-emitting area LA2, and the third light-emitting area LA3 may differ from each other. For example, the first light-emitting area LA1 may have a narrower width compared to the second light-emitting area LA2, and the first light-emitting area LA1 may have a greater width compared to the third light-emitting area LA3. Furthermore, the lengths of the first light-emitting area LA1, the second light-emitting area LA2, and the third light-emitting area LA3 may be the same.

In FIG. 4, a partial schematic cross-section of the pixel area PXA along the cutting plane I-I′ of FIG. 3 is illustrated. Referring to FIG. 4, the display panel DP may include a bottom substrate (or lower substrate) BS, a filling layer FL and a top substrate (or upper substrate) TS. The top substrate TS may be disposed on the bottom substrate BS. The filling layer FL may be disposed between the bottom substrate BS and the top substrate TS to adhere the bottom substrate BS to the top substrate TS.

The bottom substrate BS may include a bottom base substrate BBS, a circuit layer CL, a light-emitting diode layer LL, a light-emitting encapsulation layer LEL, a color control layer CCL, a bottom capping layer BCL and a spacer SPC. The bottom substrate BS may have a structure in which the circuit layer CL, the light-emitting diode layer LL, the light-emitting encapsulation layer LEL, the color control layer CCL, the bottom capping layer BCL and the spacer SPC are successively stacked on the bottom base substrate BBS. Moreover, light may be emitted from the light-emitting diode layer LL, and the color control layer CCL may be configured to receive and control the light emitted from the light-emitting diode layer LL.

The bottom base substrate BBS may be configured to serve as the foundation of the bottom substrate BS. For example, other elements may be disposed on the bottom base substrate BBS. Moreover, the bottom base substrate BBS may include various materials. For example, the bottom base substrate BBS may include glass, metal, or polymer materials. Depending on the material included in the bottom base substrate BBS, the bottom base substrate BBS may be rigid, flexible or foldable.

The circuit layer CL may be disposed on the bottom base substrate BBS and include a plurality of transistors. The plurality of transistors may be configured to transfer electrical signals to other elements as needed.

The light-emitting layer LL may include a pixel defining layer PDL, a first electrode EL1, a light-emitting layer OL and a second electrode EL2. The pixel defining layer PDL may be disposed on a portion of the circuit layer CL, and the first electrode EL1 may be disposed. As such, the first electrode EL1 may contact the area of the circuit layer CL not covered by the pixel defining layer PDL. Subsequently, the light-emitting layer OL and the second electrode EL2 may be disposed. As a result, the first electrode EL1, the light-emitting layer OL and second electrode EL2 may be stacked successively to form a plurality of light-emitting diodes.

By way of example, the pixel defining layer PDL is disposed on a portion of the circuit layer CL. Accordingly, a plurality of openings may be defined in the areas where the pixel defining layer PDL is not positioned. Moreover, the pixel defining layer PDL may be disposed to overlap the light-blocking area BA, and the plurality of openings may be disposed to overlap the plurality of light-emitting areas LA.

Furthermore, a plurality of light-emitting diodes may be formed in the plurality of openings. For example, the plurality of light-emitting diodes may be disposed to overlap the plurality of light-emitting areas LA. Moreover, the pixel defining layer PDL may surround the outer edge of each of the plurality of light-emitting diodes and may be formed to protrude in the third direction DR3. Accordingly, the light emitted from each of the light-emitting diodes may be oriented in the third direction DR3.

The first electrode EL1 is disposed on the circuit layer CL. Moreover, at least a portion of the first electrode EL1 may be in contact with the circuit layer CL. Moreover, the plurality of light-emitting diodes may be formed in the areas where the first electrode EL1 contacts the circuit layer CL. Electrical signals may be inputted to the first electrode EL1 via the circuit layer CL.

The light-emitting layer OL may be disposed on the first electrode EL1. The light-emitting layer OL may be configured to receive the electrical signals applied to the first electrode EL1 to have light emission adjusted. The light-emitting layer OL may include organic light-emitting materials, quantum dots or inorganic materials. Therefore, the plurality of light-emitting diodes may be organic light-emitting diodes, quantum dot light-emitting diodes or inorganic material-based light-emitting diodes. The light-emitting layer OL may be formed with a structure in which a plurality of layers are stacked to enhance the light-emitting efficiency and emit various wavelengths of light simultaneously.

By way of example, the light-emitting layer OL may be configured to simultaneously emit various wavelengths of light to produce white light or emit monochromatic light having a peak wavelength in a given range. The peak wavelength of the light emitted from the light-emitting layer OL may be defined as the original wavelength. Moreover, the original wavelength may be a third wavelength.

The second electrode EL2 may be disposed on the light-emitting layer OL. The second electrode EL2 may be configured to receive the electrical signals input into the light-emitting layer OL. By way of example, the electrical signals transferred from the circuit layer CL to the first electrode EL1 may pass through the light-emitting layer OL and move to the second electrode EL2. During the transfer of the electrical signals, the light-emitting layer OL may emit light.

The light-emitting encapsulation layer LEL may be disposed on the light-emitting diode layer LL. The light-emitting encapsulation layer LEL may be configured to protect the plurality of light-emitting diodes from oxygen and moisture. By way of example, the light-emitting encapsulation layer LEL may be formed as a single layer or with plurality of layers stacked together. For example, the light-emitting encapsulation layer LEL may be formed by laminating an inorganic film or an organic film as a single layer or by repeatedly stacking the inorganic film and the organic film alternately.

The color control layer CCL may include a bank BNK and a plurality of color control sections (or color control portions) CCS. The bank BNK may be disposed on a portion of the light-emitting encapsulation layer LEL, and the areas where the bank BNK is not positioned may be defined as the plurality of openings. Moreover, the plurality of color control sections CCS may be disposed, respectively, in the plurality of openings. The bank BNK may be configured to block light emitted from the light-emitting diode layer LL, and the color control sections CCS may be configured to receive the light emitted from the light-emitting diode layer LL and either emit light having a different wavelength or modify the path of the light.

By way of example, the bank BNK may be disposed on a portion of the light-emitting encapsulation layer LEL. Moreover, the plurality of openings may be defined in the areas on the light-emitting encapsulation layer LEL where the bank BNK is not disposed. A portion of the bank BNK that partitions the plurality of openings may be defined as a partition wall. Furthermore, the bank BNK may be disposed to overlap the light-blocking area BA and the pixel defining layer PDL, and the plurality of openings may be disposed to overlap the plurality of light-emitting areas LA and the plurality of light-emitting diodes. The bank BNK may be configured to absorb and block some of the light emitted from the light-emitting diodes.

The plurality of color control sections CCS may be disposed in the plurality of openings and may be disposed to overlap the plurality of light-emitting areas LA and the plurality of light-emitting diodes. Moreover, the plurality of color control sections CCS may be configured to receive and control the light emitted from the light-emitting diodes. For example, the plurality of color control sections CCS may be configured to receive some of the light and emit a different wavelength of light or modify the path of the light.

Furthermore, the plurality of color control sections CCS may have particles distributed therein. In case that light encounters the plurality of color control sections CCS, light having a different wavelength from the light incident at the plurality of color control sections CCS may be emitted or the path of the light may be modified by the particles.

The particles distributed in the plurality of color control sections CCS may be, for example, quantum dots. Quantum dots are particles whose energy band gap may be adjusted based on the size due to the quantum confinement effect. In case that quantum dots receive light with energy greater than their band gap, the quantum dots are capable of emitting light corresponding to their own energy band gap. In other words, light with a different wavelength than the incident light may be emitted.

The particles distributed in the plurality of color control sections CCS may be, for example, scattering particles. Scattering particles may scatter light incident from a given direction, thereby altering the path of the light.

The color control section CCS may include a first color control section (or first color control portion) CCS1, a second color control section (or second color control portion) CCS2 and a third color control section (or third color control portion) CCS3, each performing different roles. The first color control section CCS1 may overlap the first light-emitting area LA1, and the second color control section CCS2 may overlap the second light-emitting area LA2, while the third color control section CCS3 may overlap the third light-emitting area LA3.

By way of example, the particles distributed in the first color control section CCS1 may be quantum dots. Moreover, the quantum dots distributed in the first color control section CCS1 may be defined as first quantum dots. The first quantum dots may be configured to receive the original wavelength of light and emit a first wavelength of light.

The particles distributed in the second color control section CCS2 may be quantum dots. Moreover, the quantum dots distributed in the second color control section CCS2 may be defined as second quantum dots. The second quantum dots may be configured to receive the original wavelength of light and emit a second wavelength of light.

The particles distributed in the third color control section CCS3 may be scattering particles. The scattering particles may be configured to receive the original wavelength of light and scatter the original wavelength of light. Moreover, as described above, the original wavelength may be the third wavelength, in which case the third color control section CCS3 may be configured to emit the third wavelength of light.

The bottom capping layer BCL may be disposed on the color control layer CCL. The bottom capping layer BCL may be configured to prevent the color control layer CCL from being exposed to external moister, air or impurities, thereby preventing damage and contamination of the color control layer CCL. The bottom capping layer BCL may be omitted.

The spacer SPC may be disposed on the bottom capping layer BCL and may be disposed on the bank BNK. For example, the spacer SPC may be disposed on an area of the bank BNK defined as the partition wall. Moreover, the spacer SPC may be disposed in plurality.

The spacer SPC may be disposed between the top substrate TS and the bottom substrate BS such that the top substrate TS and the bottom substrate BS are spaced apart from each other. For example, a certain distance between the spacer SPC and the top substrate TS may be maintained to be more than about 0.3 μm and less than or equal to about 2 μm.

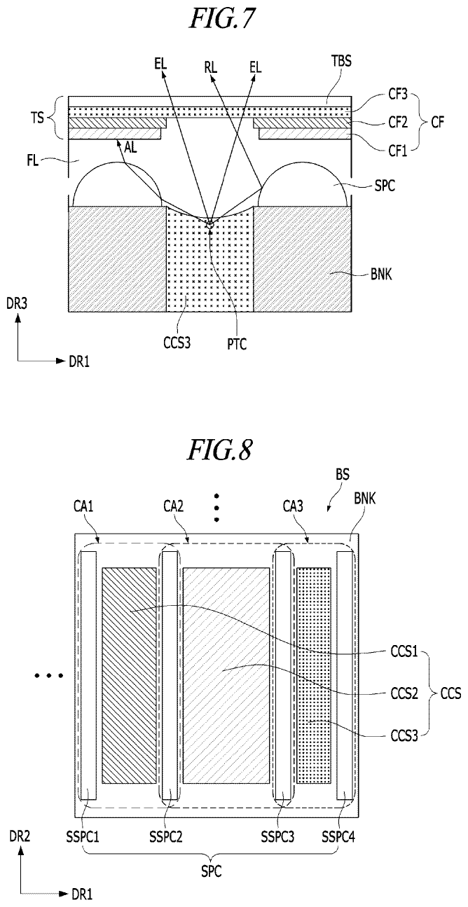

In case that the distance between the spacer SPC and the top substrate TS exceeds about 2 μm, the following issues may arise. Due to the increased distance between the bottom substrate BS and the top substrate TS, the optical efficiency may decrease. The optical effect provided by the spacer SPC may be diminished. The optical effect of the spacer SPC will be described in more detail with reference to FIG. 7.

In case that the distance between the spacer SPC and the top substrate TS is set to be less than about 0.3 μm, the following issues may arise. During the process of bonding the bottom substrate BS and the top substrate TS, the spacer SPC or the top substrate TS may be damaged if foreign substances enter between the spacer SPC and the top substrate TS.

The spacer SPC may have various cross-sectional shapes. For example, the vertically sectioned spacer SPC may have a shape in which an ellipse is combined with a rectangle, a trapezoid, a portion of an ellipse or a portion of a trapezoid. For example, the shape may be tapered in the third direction DR3.

For example, the horizontally sectioned spacer SPC may have a smaller cross-sectional area away from the bank BNK. Accordingly, an area to which the spacer SPC and the top substrate TS are adjacent may become smaller, decreasing the likelihood of foreign substances entering the area between the spacer SPC and the top substrate TS, and thereby reducing the chances of damage to the spacer SPC or the top substrate TS.

The refractive index of the spacer SPC may be between 1.3 and 1.4, inclusive. Moreover, the refractive index of the spacer SPC may be lower than that of the filling layer FL. As a result, due to the position where the spacer SPC is disposed and the refractive indices of the spacer SPC and the filling layer FL, the spacer SPC may have optical effects. The optical effects of the spacer SPC will be described in more detail with reference to FIG. 7.

Moreover, the spacer SPC may include polymer materials. For instance, the spacer SPC may include a polymer material formed by having part of polytetrafluoroethylene (PTFE) substituted. By way of example, the spacer SPC may include at least one polymeric material having a chemical formula as shown in Chemical Formula 1 to Chemical Formula 7 below.

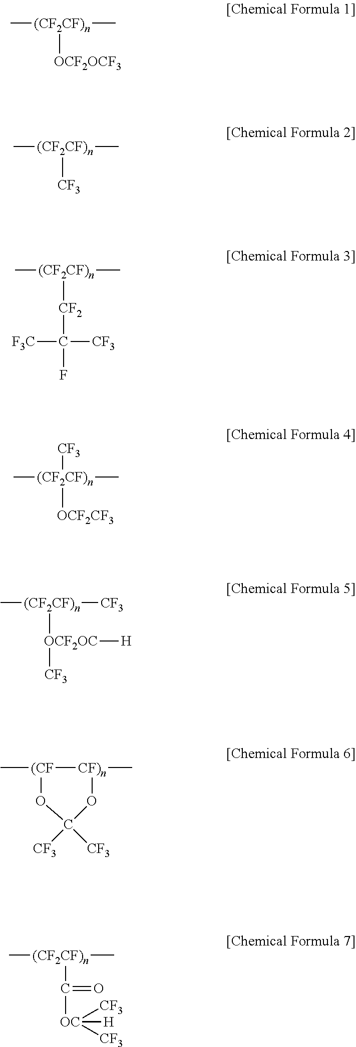

The filling layer FL may be disposed between the bottom substrate BS and the top substrate TS. Moreover, the filling layer FL may be configured to adhere the bottom substrate BS with the top substrate TS. The refractive index of the filling layer FL may be between 1.45 and 1.55, inclusive. As described above, the refractive index of the filling layer FL may be higher than the refractive index of the spacer SPC.

The top substrate TS may include a top base substrate TBS, a plurality of color filters CF, a low refraction layer LRL and a top capping layer TCL. The tops substrate TS may have a structure in which the plurality of color filters CF, the low refraction layer LRL and the top capping layer TCL are successively stacked below the top base substrate TBS. Moreover, light may be selectively transmitted or blocked by the plurality of color filters CF. The low refraction layer LRL and the top capping layer TCL may be omitted.

The top base substrate TBS may serve as the base of the top substrate TS. In other words, other elements may be disposed under or below the top base substrate TBS. The top base substrate TBS may be made of a variety of materials, for example, glass, metal, or polymer material. Depending on the material of the top base substrate TBS, the top base substrate TBS may be rigid, flexible or foldable.

The plurality of color filters CF may be disposed below the top base substrate TBS. Moreover, the plurality of color filters CF may be formed by stacking different kinds of color filters CF in a given shape. Accordingly, the plurality of color filters CF allows light emitted from the bottom substrate BS) o be selectively transmitted and blocked.

By way of example, each of the plurality of color filters CF may be configured to transmit a given wavelength band of light and block another wavelength band of light emitted from the color control layer CCL. For example, in an area where only one kind of color filter CF is arranged, the wavelength band of light that the color filter CF allows to transmit may be substantially emitted to the outside of the top substrate TS. On the other hand, in an area where a plurality of different kinds of color filters CF are superimposed, the light transmitted by one color filter CF may be substantially absorbed by another color filter CF, so that the light cannot be emitted to the outside of the top substrate TS.

Furthermore, the area where only one kind of color filter CF is arranged may be superimposed with the plurality of light-emitting areas LA, light-emitting diodes and color control sections CCS. Moreover, the area where the plurality of different kinds of color filters CF are superimposed may be superimposed with the light-blocking area BA, the pixel defining layer PDL and the bank BNK.

For example, the plurality of color filters CF may include a first color filter CF1, a second color filter CF2, and a third color filter CF3 that transmit and absorb different wavelength bands of light.

By way of example, the first color filter CF1 may allow a first wavelength of light and block other wavelengths of light. The second color filter CF2 may allow a second wavelength of light and block other wavelengths of light. The third color filter CF3 may allow a third wavelength of light and block other wavelengths of light.

An area where only the first color filter CF1 is arranged may be superimposed with the first light-emitting area LA1, and an area where only the second color filter CF2 is arranged may be superimposed with the second light-emitting area LA2, while an area where only the third color filter CF3 is arranged may be superimposed with the third light-emitting area LA3. An area where two or more kinds of the first color filter CF1, the second color filter CF2 and the third color filter CF3 may be superimposed with the light-blocking area BA.

The low refraction layer LRL may be disposed below the plurality of color filters CF. Moreover, the low refraction layer LRL may have a lower refractive index than the filling layer FL. Since the low refraction layer LRL has a relatively low refractive index, the light may be refracted in the low refraction layer LRL, thereby increasing the optical efficiency of the display panel DP. The low refraction layer LRL may be omitted.

The top capping layer TCL may be disposed below the low refraction layer LRL. The top capping layer TCL may be configured to prevent the low refraction layer LRL and the plurality of color filters CF from being exposed to external moisture, air or impurities, thereby preventing the low refraction layer LRL and the plurality of color filters CF from being damaged and contaminated. The top capping layer TCL may be omitted.

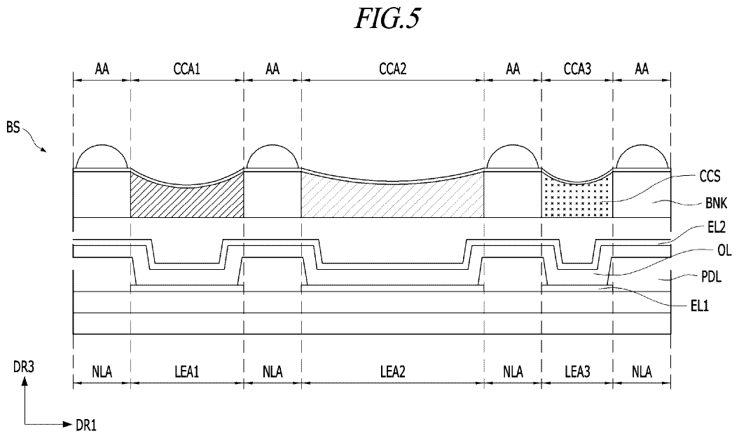

FIG. 5 is a separate illustration of the bottom substrate BS from the schematic cross-section illustrated in FIG. 4.

Referring to FIG. 5, in the bottom substrate BS according to an embodiment, a plurality of light-emitting diode areas LEA1, LEA2, and LEA3, a non-light-emitting area NLA, a plurality of color control areas CCA1, CCA2, and CCA3, and a light-absorbing area AA are defined. The plurality of light-emitting diode areas LEA1, LEA2, and LEA3 and the plurality of color control areas CCA1, CCA2, and CCA3 may overlap each other, and the non-light-emitting area NLA and the light-absorbing area AA may overlap each other.

The plurality of light-emitting diode areas LEA1, LEA2, and LEA3 may be defined as areas where the plurality of light-emitting diodes are located or disposed, for example, areas where the pixel defining layer PDL is not located or disposed. Moreover, the plurality of light-emitting diode areas LEA1, LEA2, and LEA3 may overlap the plurality of light-emitting areas LA. Substantially, the plurality of light-emitting diode areas LEA1, LEA2, and LEA3 may be areas where light is emitted from the light-emitting diode layer (LL). By way of example, the plurality of light-emitting diode areas LEA1, LEA2, and LEA3 may be areas where the original wavelength of light is emitted. The original wavelength may be the same as the third wavelength.

The non-light-emitting area NLA may be defined as an area in which the pixel defining layer PDL is disposed. Moreover, the non-light-emitting area NLA may overlap the light-blocking area BA. Substantially, the non-light-emitting area NLA may be an area on the light-emitting diode layer LL where light is not emitted.

The plurality of color control areas CCA1, CCA2, and CCA3 may be defined as areas in which the plurality of color control sections CCS are disposed. Moreover, the plurality of color control areas CCA1, CCA2, and CCA3 may overlap the plurality of light-emitting areas LA. Substantially, the plurality of color control areas CCA1, CCA2, and CCA3 may be areas on the color control layer CCL where the original wavelength of light is received, and a wavelength of light different from the original wavelength of light is emitted, or the path of the original wavelength of light is altered.

The light-absorbing area AA may be defined as an area where the bank (BNK) is located or disposed. The light-absorbing area AA may overlap the light-blocking area BA. Substantially, the light-absorbing area AA may be an area on the color control layer CCL where the original wavelength of light is received and absorbed and blocked.

The plurality of light-emitting diode areas LEA1, LEA2, and LEA3 may include a first light-emitting diode area LEA1, a second light-emitting diode area LEA2 and a third light-emitting diode area LEA3. Moreover, the color control areas CCA1, CCA2, and CCA3 may include a first color control area CCA1, a second color control area CCA2 and a third color control area CCA3.

Furthermore, the area where the first light-emitting diode area LEA1 is defined may overlap the first color control area CCA1. The area where the second light-emitting diode area LEA2 is defined may overlap the second color control area CCA2. The area where the third light-emitting diode area LEA3 is defined may overlap the third color control area CCA3.

As a result, a plurality of lights emitted from the bottom substrate BS may be emitted through one of the following paths. The third wavelength of light emitted from the first light-emitting diode area LEA1 may reach the first quantum dots included in the first color control area CCA1. Therefore, the first wavelength of light may be emitted from the first color control area CCA1.

Moreover, the third wavelength of light emitted from the second light-emitting diode area LEA2 may reach the second quantum dots included in the second color control area CCA2. Therefore, the second wavelength of light may be emitted from the second color control area CCA2.

Furthermore, the third wavelength of light emitted from the third light-emitting diode area LEA3 may reach the scattering particles included in the third color control area CCA3. Therefore, the third wavelength of light may be emitted from the third color control area CCA3.

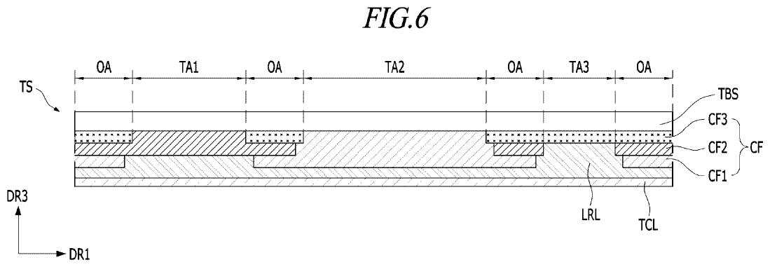

FIG. 6 is the top substrate TS separately illustrated from the schematic cross-section shown in FIG. 4.

Referring to FIG. 6, the top substrate TS in accordance with an embodiment has a plurality of transmissive areas TA1, TA2, and TA3 and an opaque area OA.

The plurality of transmissive areas TA1, TA2, and TA3 may be defined as areas in which only a single kind of color filter CF is disposed. Moreover, the plurality of transmissive areas TA1, TA2, and TA3 may overlap the plurality of light-emitting areas LA. Substantially, the plurality of transmissive areas TA1, TA2, and TA3 may be areas on the plurality of color filters CF where light is emitted to the outside from the top substrate TS.

The opaque area OA may be defined as an area where multiple kinds of the plurality of color filters CF are superposed. Moreover, the opaque area OA may overlap the light-blocking area BA. Substantially, the opaque area OA may be an area on the plurality of color filters CF where light is not emitted to the outside from the top substrate TS.

The plurality of transmissive areas TA1, TA2, and TA3 may include a first transmissive area TA1, a second transmissive area TA2 and a third transmissive area TA3.

The area in which the first transmissive area TA1 is defined may be an area through which the first wavelength of light may pass and be emitted to the outside of the top substrate TS. The first transmissive area TA1 may overlap the first light-emitting area LA1. Substantially, the first transmissive area TA1 may be an area where only the first color filter CF1 of the plurality of color filters CF is placed.

The area in which the second transmissive area TA2 is defined may be an area through which the second wavelength of light may pass and be emitted to the outside of the top substrate TS. The second transmissive area TA2 may overlap the second light-emitting area LA2. Substantially, the second transmissive area TA2 may be an area where only the second color filter CF2 of the plurality of color filters CF is placed.

The area in which the third transmissive area TA3 is defined may be an area through which the third wavelength of light may pass and be emitted to the outside of the top substrate TS. The third transmissive area TA3 may overlap the third light-emitting area LA3. Substantially, the third transmissive area TA3 may be an area where only the third color filter CF3 of the plurality of color filters CF is placed.

As a result, the plurality of lights emitted to the outside of the top substrate TS may be emitted through one of the following paths. The first wavelength of light emitted from the first color control area CCA1 may pass through the first color filter CF1 and may not be blocked by the second color filter CF2 or the third color filter CF3. Therefore, it is possible for the first wavelength of light to pass through the first transmissive area TA1.

The second wavelength of light emitted from the second color control area CCA2 may pass through the second color filter CF2 and may not be blocked by the first color filter CF1 or the third color filter CF3. Therefore, it is possible for the second wavelength of light to pass through the second transmissive area TA2.

The third wavelength of light scattered from the third color control area CCA3 may pass through the third color filter CF3 and may not be blocked by the first color filter CF1 or the second color filter CF2. Therefore, it is possible for the third wavelength of light to pass through the third transmissive area TA3.

FIG. 7 is a magnified view of the schematic cross-section shown in FIG. 4, further illustrating the path of light, and with some elements omitted.

Referring to FIG. 7, the vicinity of the third color control section CCS3 is enlarged from the schematic cross-sectional view of FIG. 4. A particle (PTC), a path of emitted light (EL), a path of reflected light (RL) and a path of refracted light (AL) are further illustrated. Furthermore, for the sake of a more efficient description of the optical effects of the spacer SPC, the bottom capping layer BCL, the low refraction layer LRL and the top capping layer TCL are omitted.

The particle PTC represents one of the particles dispersed in the third color control section CCS3. Moreover, the particle PTC may be a scattering particle. Accordingly, it is possible to scatter the original wavelength of light to result in the paths of emitted light EL, reflected light RL and refracted light AL. The original wavelength may be set as the third wavelength. Therefore, the emitted light EL, reflected light RL and refracted light AL, which have the original wavelength, may pass through the third color filter CF3 but may be blocked by the first color filter CF1 and the second color filter CF2.

The emitted light EL may be a part of the light scattered from the particle PTC and may be relatively oriented in the third direction (or upper direction) DR3. After having been scattered from the particle PTC, the emitted light EL may pass through the third color filter CF3 and may be emitted to the outside of the top substrate TS.

The reflected light RL may be a part of the light scattered from the particle PTC and may be oriented in the lateral direction DR1 compared to the emitted light EL. After having been scattered from the particle PTC, the reflected light RL may be reflected by the spacer SPC and pass through the third color filter CF3 to be emitted to the outside of the top substrate TS.

In other words, the reflected light RL may be the light that can be emitted to the outside of the top substrate TS by the optical effects of the spacer SPC. The path of reflected light RL demonstrates that the optical efficiency of the display panel DP may be enhanced by the spacer SPC.

Moreover, the optical effects described above may be much better in case that the refractive index of the spacer SPC is lower than the refractive index of the filling layer FL. By way of example, in the case where the refractive index of the spacer SPC is set to be lower than that of the filling layer FL, the light reflected by the spacer SPC may undergo total internal reflection. This phenomenon of total internal reflection may lead to a relatively increased amount of reflected light RL. Accordingly, the optical efficiency of the display panel DP may be further enhanced.

If, contrary to the embodiment, the refractive index of the spacer SPC is higher than that of the filling layer FL, the light reflected by the spacer SPC may not undergo total internal reflection. As a result, the optical efficiency of the display panel DP may be relatively less enhanced.

The refracted light AL may be a part of the light scattered from the particle PTC and may be oriented relatively in a latera direction (for example, opposite to DR1) compared to the reflected light RL. After having been scattered from the particle PTC, the refracted light AL may be refracted in the spacer SPC and absorbed by the color filter CF. Accordingly, the refracted light AL may not affect other pixel areas PXA or other color control sections CCS1, CCS2. Therefore, the color reproduction of the display panel DP may be improved.

The optical effects described above can occur in case that the refractive index of the spacer SPC is lower than that of the filling layer FL. By way of example, by having the refractive index of the spacer SPC set to be lower than that of the filling layer FL, the refracted light AL may be refracted relatively in the upper direction DR3. Accordingly, the angle of incidence of the refracted light AL on the top substrate TS may become relatively smaller. Therefore, the refracted light AL may be absorbed by the color filter CF, leading to an improvement in the color reproduction of the display panel DP.

If, contrary to the embodiment, the spacer SPC is not disposed, the refracted light AL may pass through the third color filter CF3 located or disposed in another pixel area PXA and may be emitted to the outside of the top substrate TS. Therefore, the refracted light AL may affect other pixel areas PXA, and the color reproduction of the display panel DP may be degraded.

Moreover, due to a large angle of incidence, the refracted light AL may be reflected by the top substrate TS and directed toward the bottom substrate BS. Since the refracted light AL is of the original wavelength, the first and second wavelengths of light may be emitted if the first color control section CCS1 and the second color control section CCS2 receive the refracted light AL. Therefore, different wavelengths of light may be emitted due to the refracted light AL, causing a degraded color reproduction of the display panel DP.

Furthermore, contrary to the embodiment, if the spacer SPC is disposed but has a higher refractive index than the filling layer FL does, the refracted light AL may be refracted in more lateral direction (for example, opposite to DR1). Therefore, the refracted light AL may affect other pixel areas PXA, and different wavelengths of light may be emitted due to the refracted light AL, thereby possibly degrading the color reproduction of the display panel DP.

Although the path of the third wavelength of light is illustrated as an example, the effects of the spacer SPC may be the same or similar for the first and second wavelengths of light.

FIG. 8 is an illustration of the pixel area PXA of the bottom substrate BS according to an embodiment.

Referring to FIG. 8, in a single pixel area PXA, a first adjacent area CA1, a second adjacent area CA2, and a third adjacent area CA3 may be defined on a portion of the bank BNK of the bottom substrate BS. Moreover, the spacer SPC may be extended and disposed on the first adjacent area CA1, the second adjacent area CA2 or the third adjacent area CA3.

The first color control section CCS1 and the second color control section CCS2 may be arranged to be adjacent to each other. Moreover, the second color control section CCS2 and the third color control section CCS3 may be arranged to be adjacent to each other.

By way of example, to define the first adjacent area CA1, the second adjacent area CA2 and the third adjacent area CA3, an adjacent distance may be defined first. The adjacent distance may be defined as the smallest value among the distance between the first color control section CCS1 and the second color control section CCS2, the distance between the first color control section CCS1 and the third color control section CCS3 and the distance between the second color control section CCS2 and the third color control section CCS3.

Referring to FIG. 8 as an example, in the case where the first color control section CCS1 and the second color control section CCS2 are separated by a first distance, and the second color control section CCS2 and the third color control section CCS3 are separated by a second distance, the smaller value between the first distance and the second distance may be defined as the adjacent distance.

The first adjacent area CA1 may be defined as a portion of the bank BNK that is spaced apart from the first color control section CCS1. Similarly, the second adjacent area CA2 may be defined as a portion of the bank BNK that is spaced apart from the second color control section CCS2. Moreover, the third adjacent area CA3 may be defined as a portion of the bank BNK that is spaced apart from the third color control section CCS3.

In case that the spacer SPC is disposed on the first adjacent area CA1, the second adjacent area CA2 or the third adjacent area CA3, light may be reflected by the spacer SPC, and the optical efficiency of the display panel DP may be increased.

Moreover, areas where the adjacent areas overlap each other may be defined as overlapping areas. For example, the area where the first adjacent area CA1 overlaps the second adjacent area CA2, the area where the first adjacent area CA1 overlaps the third adjacent area CA3 and the area where the second adjacent area CA2 overlaps the third adjacent area CA3 may be defined as the overlapping areas.

For instance, in FIG. 8, the area where the first adjacent area CA1 overlaps the second adjacent area CA2 and the area where the second adjacent area CA2 overlaps the third adjacent area CA3 may be defined as the overlapping areas.

In the case where the spacer SPC is disposed in the overlapping areas, the light may be refracted by the spacer SPC, thereby preventing a phenomenon of degraded color reproduction caused by the light emitted from a given color control section CCS entering another color control section CCS.

By way of example, in the embodiment, the plurality of color control sections CCS1, CCS2, and CCS3 may each extend in the second direction DR2. Moreover, the plurality of color control sections CCS1, CCS2, and CCS3 may be arranged in the first direction DR1.

In a single pixel area PXA, the spacer SPC may include a plurality of sub-spacers SSPC1-SSPC4. The plurality of sub-spacers SSPC1-SSPC4 may each extend in the second direction DR2. Moreover, the plurality of sub-spacers SSPC1-SSPC4 may be arranged in the first direction DR1.

Accordingly, the plurality of sub-spacers SSPC1-SSPC4 may be adjacent to the plurality of color control sections CCS in larger areas. Therefore, the optical efficiency and the color reproduction may be increased by the plurality of sub-spacers SSPC1-SSPC4.

Hereinafter, other embodiments will be described in detail with reference to the accompanying drawings.

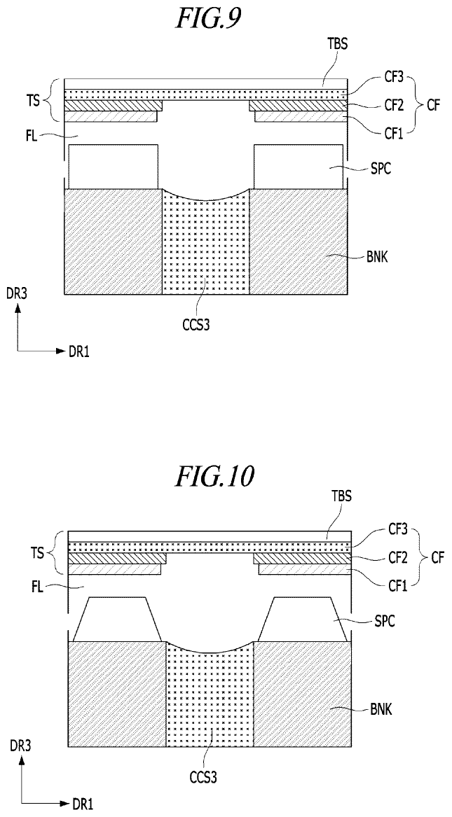

FIG. 9 is a magnified schematic cross-sectional view of the pixel area PXA according to an embodiment. FIG. 9 may correspond to the magnified view shown in FIG. 7.

Referring to FIG. 9, the cross-section of the spacer SPC may be rectangular. As such, a relatively large amount of light may contact the lateral surfaces of the spacer SPC. Therefore, the amount of light reflected by and refracted through the spacer SPC may increase. As a result, it is possible to improve the light efficiency and color reproduction of the display panel DP.

FIG. 10 is a magnified schematic cross-sectional view of the pixel area PXA according to an embodiment. FIG. 10 may correspond to the magnified view shown in FIG. 7.

Referring to FIG. 10, the cross-section of the spacer SPC may be trapezoidal. Accordingly, the angle of incidence of the light incident at the lateral surfaces of the spacer SPC may be relatively large. Therefore, total internal reflection may occur more readily at the lateral surfaces of the spacer SPC. Therefore, the light efficiency of the display panel DP can be further increased.

Moreover, the cross-sectional area of each spacer SPC may become smaller away from the bank BNK. Accordingly, the area of the portion of the spacer SPC adjacent to the top substrate TS may become smaller. Therefore, the spacer SPC or the top substrate TS may be less likely damaged by foreign substances.

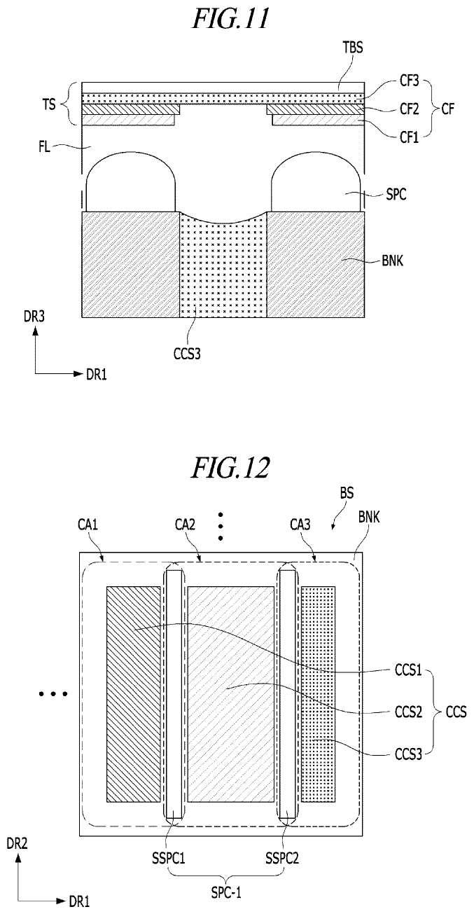

FIG. 11 is a magnified schematic cross-sectional view of the pixel area PXA according to an embodiment. FIG. 11 may correspond to the magnified view shown in FIG. 7.

Referring to FIG. 11, the cross-section of the spacer SPC may have a shape in which a rectangle and a portion of an ellipse are combined. As a result, a relatively large amount of light can contact the lateral surfaces of the spacer SPC. Therefore, it becomes possible to further improve the light efficiency and color reproduction of the display panel DP.

Moreover, according to the embodiment, the cross-sectional area of each spacer SPC may become smaller away from the bank BNK, eventually becoming a line. Accordingly, the area of the portion of the spacer SPC adjacent to the top substrate TS may become smaller. Therefore, the spacer SPC or the top substrate TS may be less likely damaged by foreign substances.

FIG. 12 is an illustration of the pixel area PXA of the bottom substrate BS according to an embodiment.

Referring to FIG. 12, in a single pixel area PXA, a spacer SPC-1 disposed on the bottom substrate BS may include 2 sub-spacers SSPC1 and SSPC2. Moreover, the first color control section CCS1, the second color control section CCS2 and the third color control section CCS3 may each extend in the second direction DR2.

By way of example, the spacer SPC-1 may include a first sub-spacer SSPC1 disposed between the first color control section CCS1 and the second color control section CCS2 and extending in the second direction DR2.

Moreover, the spacer SPC-1 may further include a second sub-spacer SSPC2, which is disposed between the second color control section CCS2 and the third color control section CCS3, extended in the second direction DR2, and spaced apart from the first sub-spacer SSPC1.

The plurality of sub-spacers SSPC1 and SSPC2 may be disposed on the overlapping areas described above. Accordingly, the color reproduction of the display panel DP may be improved. Moreover, by selectively disposing the plurality of sub-spacers SSPC1 and SSPC2 on the overlapping areas only, it becomes possible to save the manufacturing cost. Moreover, the area to which the plurality of sub-spacers SSPC1 and SSPC2 and the top substrate TS are adjacent may become smaller, thereby reducing the probability of damage to the plurality of sub-spacers SSPC1 and SSPC2 and the top substrate TS caused by foreign substances.

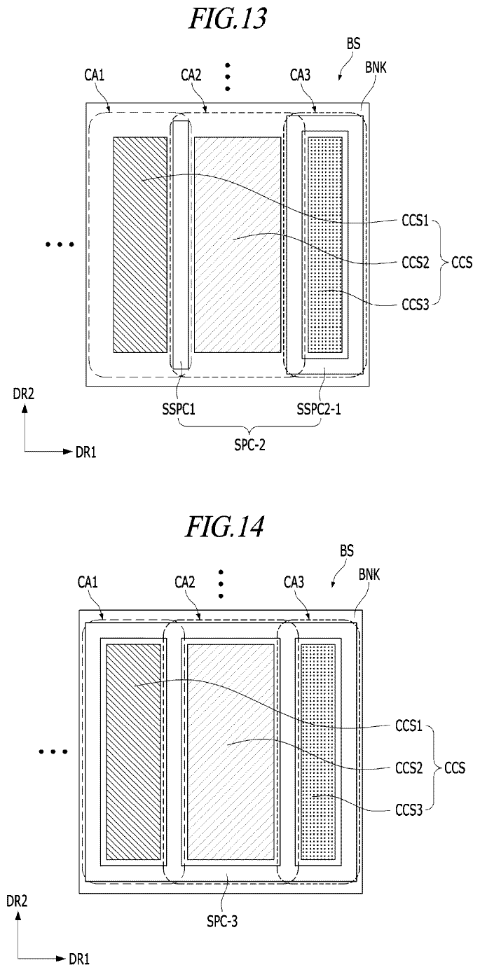

FIG. 13 is an illustration of the pixel area PXA of the bottom substrate BS according to an embodiment.

Referring to FIG. 13, in a single pixel area PXA, a spacer SPC-2 disposed on the bottom substrate BS may include 2 sub-spacers SSPC1 and SSPC2-1. Moreover, the first color control section CCS1, the second color control section CCS2 and the third color control section CCS3 may each extend in the second direction DR2.

By way of example, the spacer SPC-2 may include a first sub-spacer SSPC1 disposed between the first color control section CCS1 and the second color control section CCS2 and extending in the second direction DR2.

Moreover, the spacer SPC-2 may further include a second sub-spacer SSPC2-1 having a shape surrounding the third color control section CCS3 in plan view.

Accordingly, since one of the plurality of sub-spacers SSPC1 and SSPC2-1 surrounds the third color control section CCS3, it is possible to further enhance the optical efficiency of the third color control section CCS3, which has a relatively smaller area than the first color control section CCS1 or the second color control section CCS2. Therefore, the optical efficiency of the display panel DP may be increased. Moreover, the effect of the third wavelength of light to the first color control section CCS1 and the second color control section CCS2 may become less. Therefore, the color reproduction of the display panel DP may be improved.

FIG. 14 is an illustration of the pixel area PXA of the bottom substrate BS according to an embodiment.

Referring to FIG. 14, in a single pixel area PXA, a single spacer SPC-3 may be disposed on the bottom substrate BS. Moreover, the first color control section CCS1, the second color control section CCS2 and the third color control section CCS3 may each extend in the second direction DR2.

By way of example, the spacer SPC-3 may have a shape surrounding each of the first color control section CCS1, the second color control section CCS2 and the third color control section CCS3.

Accordingly, by having the spacer SPC-3 surround each of the first color control section CCS1, the second color control section CCS2 and the third color control section CCS3, the plurality of color control sections CCS may have an enhanced optical efficiency. As a result, the display panel DP may have an enhanced optical efficiency. Moreover, the plurality of color control sections CCS may have less effect to each other. Therefore, the color reproduction of the display panel DP be improved.

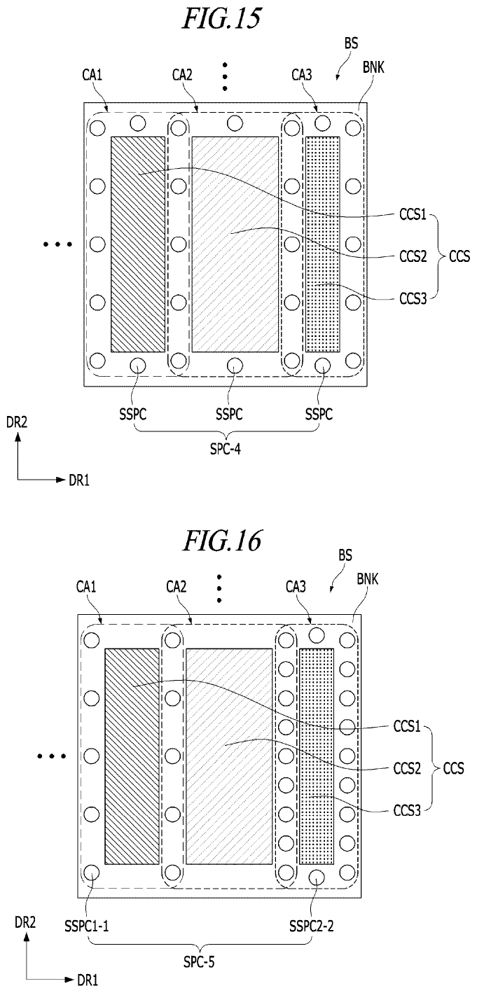

FIG. 15 is an illustration of the pixel area PXA of the bottom substrate BS according to an embodiment.

Referring to FIG. 15, in a single pixel area PXA, a spacer SPC-4 disposed on the bottom substrate BS may include a plurality of sub-spacers SSPC. Moreover, the first color control section CCS1, the second color control section CCS2 and the third color control section CCS3 may each extend in the second direction DR2.

By way of example, the plurality of sub-spacers SSPC may have a ratio of greater than or equal to about 0.5 and smaller or less than or equal to about 2 between a width in a selectable direction and a width in a direction perpendicular to the selectable direction. For example, the plurality of sub-spacers SSPC may have a circular or elliptical shape.

The shapes of the plurality of sub-spacers SSPC in an embodiment may differ from the shapes of the plurality of sub-spacers SSPC1-SSPC4 in accordance with other embodiments. Nevertheless, the spacer SPC-4 illustrated in FIG. 15 may have optical effects that are the same as or similar to those of the spacers SPC, SPC-1, SPC-2, and SPC-3 in other embodiments.

By way of example, the plurality of sub-spacers SSPC may be repeatedly arranged to surround each of the first color control section CCS1, the second color control section CCS2 and the third color control section CCS3. As a result, the optical efficiency of the plurality of color control sections CCS may be increased by the plurality of sub-spacers SSPC. Thus, the optical efficiency of the display panel DP may be enhanced. Furthermore, the plurality of sub-spacers SSPC may reduce the mutual influence between the plurality of color control sections CCS. As a result, the color reproduction of the display panel DP may be improved.

The plurality of sub-spacers SSPC may be repeatedly arranged with relatively narrow areas. Accordingly, the production cost for the plurality of sub-spacers SSPC may be relatively low. Moreover, since the area adjacent between the plurality of sub-spacers SSPC and the top substrate TS is reduced, there may be a lower probability of damage to the plurality of sub-spacers SSPC or the top substrate TS caused by foreign substances.

FIG. 16 is an illustration of the pixel area PXA of the bottom substrate BS according to a different embodiment.

Referring to FIG. 16, in a single pixel area PXA, a spacer SPC-5 disposed on the bottom substrate BS may include a plurality of sub-spacers SSPC1-1, and SSPC2-2. Moreover, the first color control section CCS1, the second color control section CCS2 and the third color control section CCS3 may each extend in the second direction DR2.

By way of example, the plurality of sub-spacers SSPC1-1 and SSPC2-2 may have a ratio of greater than or equal to about 0.5 and smaller or less than or equal to about 2 between a width in a selectable direction and a width in a direction perpendicular to the selectable direction. For example, the plurality of sub-spacers SSPC1-1, and SSPC2-2 may have a circular or elliptical shape.

Among the plurality of sub-spacers SSPC1-1 and SSPC2-2, first sub-spacers SSPC1-1 may be disposed on a first adjacent area CA1, and second sub-spacers SSPC2-2 may be disposed on a third adjacent area CA3.

Moreover, the number of the plurality of second sub-spacers SSPC2-2 may be greater than the number of the plurality of first sub-spacers SSPC1-1.

For example, as the plurality of sub-spacers SSPC1-1 and SSPC2-2 may be more densely arranged in the vicinity of the third color control section CCS3, the optical efficiency of the third color control section CCS3, which has a relatively smaller area than the first color control section CCS1 or the second color control section CCS2, may be enhanced. Therefore, the optical efficiency of the display panel DP may be increased. Moreover, the third wavelength of light may have a less influence on the first color control section CCS1 and the second color control section CCS2. Therefore, the color reproduction of the display panel DP may be improved.

FIG. 17 is an illustration of the pixel area PXA of the bottom substrate BS according to a different embodiment.

Referring to FIG. 17, in a single pixel area PXA, a spacer SPC-6 disposed on the bottom substrate BS may include 4 sub-spacers SSPC1, SSPC2, SSPC3-1, and SSPC4-1. Moreover, the first color control section CCS1, the second color control section CCS2 and the third color control section CCS3-1 may each extend in the second direction DR2. The color control section CCS3-1 may be shorter than each of the first color control section CCS1 and the second color control section CCS2.

The plurality of color control sections CCS-1 illustrated in FIG. 17 may have a different shape than the plurality of color control sections CCS illustrated in other drawings. Nonetheless, the spacers SPC-6 may have the optical effect that is the same as or similar to the spacers SPC, SPC-1, SPC-2, SPC-3, SPC-4, and SPC-5 illustrated in other drawings.

By way of example, the plurality of sub-spacers SSPC1, SSPC2, SSPC3-1, and SSPC4-1 may be extended in the second direction DR2 and disposed on the first adjacent area CA1, the second adjacent area CA2 or the third adjacent area CA3 described above. Accordingly, the optical efficiency of the plurality of color control sections CCS-1 may be increased, and the optical efficiency of the display panel DP may be increased. Moreover, the mutual influence between the plurality of color control sections CCS-1 may be reduced, and the color reproduction of the display panel DP may be improved.

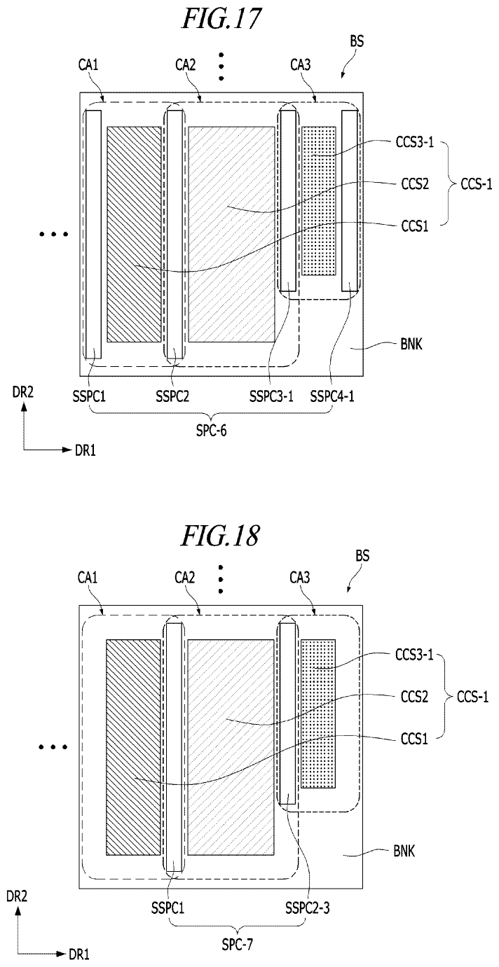

FIG. 18 is an illustration of the pixel area of the bottom substrate according to a different embodiment.

Referring to FIG. 18, in a single pixel area PXA, a spacer SPC-7 disposed on the bottom substrate BS may include 2 sub-spacers SSPC1 and SSPC2-3.

By way of example, the spacer SPC-7 may include a first sub-spacer SSPC1 disposed between the first color control section CCS1 and the second color control section CCS2 and extending in the second direction DR2.

Moreover, the spacer SPC-7 may further include a second sub-spacer SSPC2-3, which is disposed between the second color control section CCS2 and the third color control section CCS, extended in the second direction DR2, and spaced apart from the first sub-spacer SSPC1.

The plurality of sub-spacers SSPC1 and SSPC2-3 may be disposed on the overlapping area described above. Accordingly, the color reproduction of the display panel DP may be enhanced.

Moreover, by selectively disposing the plurality of sub-spacers SSPC1, SSPC2-3 on the overlapping areas only, it becomes possible to save the manufacturing cost, and the areas of the portions of the plurality of sub-spacers SSPC1 and SSPC2-3 adjacent to the top substrate TS may become smaller. Therefore, the probability of damage to the plurality of sub-spacers SSPC1 and SSPC2-3 or the top substrate TS caused by foreign substances may be reduced.

FIG. 19 is an illustration of the pixel area of the bottom substrate according to a different embodiment.

Referring to FIG. 19, in a single pixel area PXA, a spacer SPC-8 disposed on the bottom substrate BS may include 2 sub-spacers SSPC1 and SSPC2-4.

By way of example, the spacer SPC-8 may include a first sub-spacer SSPC1 disposed between the first color control section CCS1 and the second color control section CCS2 and extending in the second direction DR2.

Moreover, the spacer SPC-8 may further include a second sub-spacer SSPC2-4 having a shape surrounding the third color control section CCS3-1 in plan view.

Accordingly, since one of the plurality of sub-spacers SSPC1 and SSPC2-4 surrounds the third color control section CCS3-1, it is possible to further enhance the optical efficiency of the third color control section CCS3-1, which has a relatively smaller area than the first color control section CCS1 or the second color control section CCS2. Therefore, the optical efficiency of the display panel DP may be increased. Moreover, the effect of the third wavelength of light to the first color control section CCS1 and the second color control section CCS2 may become less. Therefore, the color reproduction of the display panel DP may be improved.

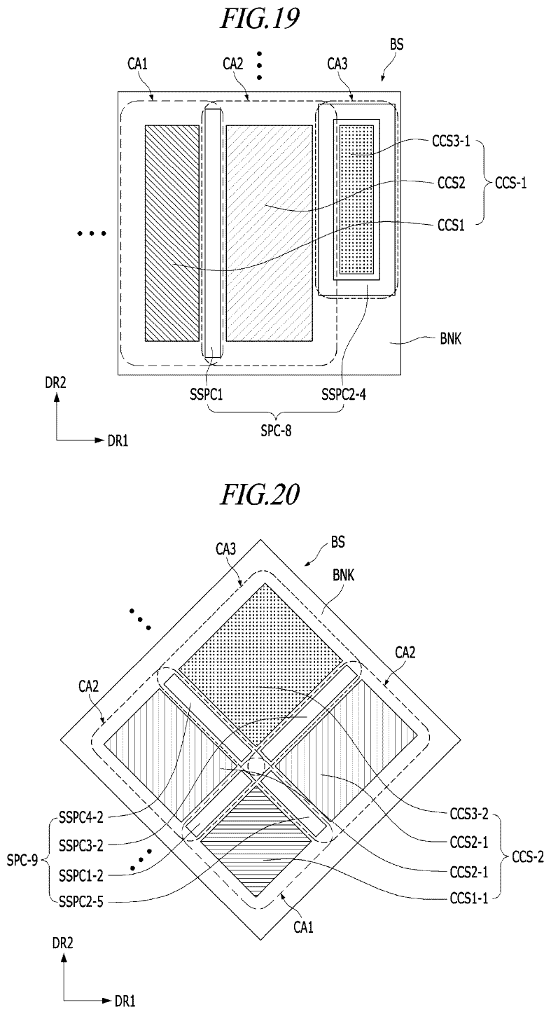

FIG. 20 is an illustration of the pixel area of the bottom substrate according to another different embodiment.

Referring to FIG. 20, in a single pixel area PXA, a spacer SPC-9 disposed on the bottom substrate BS may include 4 sub-spacers SSPC1-2, SSPC2-5, SSPC3-2, and SSPC4-2. The pixel area PXA may be a rectangle tilted by about a 45-degree angle, and each of a first color control section CCS1-1, a second color control section CCS2-1 and a third color control section CCS3-2 may also be a rectangle tilted by about a 45-degree angle. There may be 2 second color control sections CCS2-1 arranged.

The shapes of the pixel area PXA and the plurality of color control sections CCS-2 illustrated in FIG. 20 may differ from the shapes of the pixel area PXA and the plurality of color control sections CCS, and CCS-1 illustrated in other drawings. Nonetheless, the spacers SPC-9 may have the same or like optical effects as the spacers SPC-8 illustrated in other drawings.

By way of example, the plurality of sub-spacers SSPC1-2, SSPC2-5, SSPC3-2, and SSPC4-2 may be arranged by being extended in a direction tilted by about a 45-degree angle. For instance, in plan view, 2 sub-spacers SSPC1-2, and SSPC2-5 may be disposed between the first color control section CCS1-1 and the second color control section CCS2-1. Furthermore, 2 sub-spacers SSPC3-2, and SSPC4-2 may be further disposed between the second color control section CCS2-1 and the third color control section CCS3-2 in plan view.

Accordingly, the plurality of sub-spacers SSPC1-2, SSPC2-5, SSPC3-2, and SSPC4-2 may be disposed on the first adjacent area CA1, the second adjacent area CA2 or the third adjacent area CA3. As a result, the optical efficiency of the plurality of color control sections CCS-2 may be further enhanced, thereby increasing the optical efficiency of the display panel DP. Moreover, the plurality of sub-spacers SSPC1-1, SSPC2-4, SSPC3-2, and SSPC4-2 may be disposed on the overlapping areas, resulting in the improvement of color reproduction of the display panel DP.

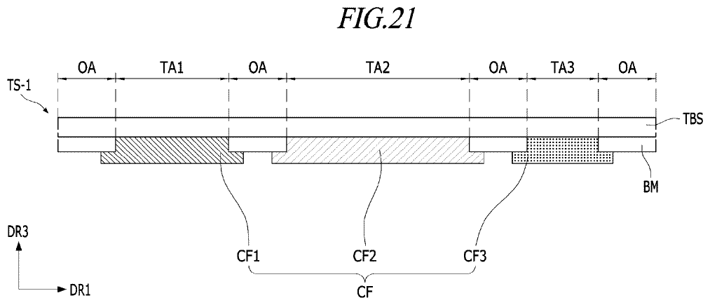

FIG. 21 is an illustration of a partial schematic cross-sectional view of a top substrate TS-1 according to an embodiment.

The top substrate TS-1 shown in FIG. 21 may further include light-blocking portion BM Moreover, the area where the light-blocking portion BM is placed may be defined as an opaque area OA. On the other hand, the area where the light-blocking portion BM is not placed may be defined as a transmissive area TA.

The light-blocking portion BM may be configured to absorb and block light of the first wavelength of light, the second wavelength of light and the third wavelength of light. Therefore, the opaque area OA may be defined with the area where the light-blocking portion BM is disposed.

The transmissive area TA may be defined with the area where the light-blocking portion BM is not placed. For example, the area where the first color filter CF1 is placed may be defined as a first transmissive area TA1, and the area where the second color filter CF2 is placed may be defined as a second transmissive area TA2, while the area where the third color filter CF3 is placed may be defined as a third transmissive area TA3.

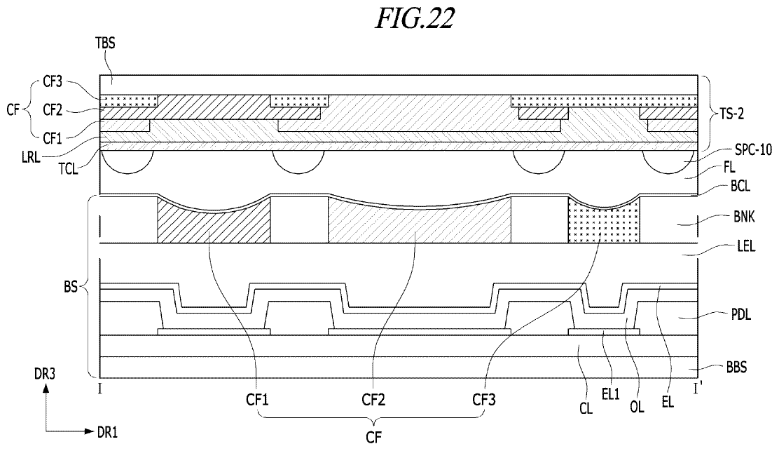

FIG. 22 is an illustration of a partial schematic cross-section taken along line I-I′ of FIG. 3.

Referring to FIG. 22, in the schematic cross-sectional view of the display panel DP according to an embodiment, a spacer SPC-10 is disposed on a top substrate TS-2. Moreover, the spacer SPC-10 may be positioned over the bank BNK.

The spacer SPC-10 may be disposed on the top substrate TS-2 to allow constant the top substrate TS-2 and the bottom substrate BS disposed with a selectable distance apart from each other. Other than being positioned on the top substrate TS-2, the spacer SPC-10 may be substantially the same as the spacers SPC-SPC-9 in other embodiments described above.

Hereinafter, a method of manufacturing the above-described display panel in accordance with an embodiment will be described.

The method of manufacturing the display panel in accordance with an embodiment may include manufacturing a bottom substrate, manufacturing a top substrate and bonding. In the step of manufacturing a bottom substrate, the bottom substrate BS may be manufactured. In the step of manufacturing a top substrate, the top substrate TS may be manufactured. In the step of bonding, the filling layer FL may be filled between the top substrate TS and the bottom substrate BS to bond the bottom substrate BS with the top substrate TS.

In the step of manufacturing a bottom substrate, the bottom substrate BS may be formed. The step of manufacturing a bottom substrate may include forming a circuit layer, forming a light-emitting diode layer, forming a light-emitting encapsulation layer, forming a color control layer, forming a bottom capping layer, and forming a spacer.

In the step of forming a circuit layer, the circuit layer CL may be formed on the bottom base substrate BBS.

In the step of forming a light-emitting diode layer, the light-emitting diode layer LL may be formed. Moreover, the step of forming a light-emitting diode layer may include forming a pixel defining layer, forming a first electrode, forming a light-emitting layer, and forming a second electrode.

By way of example, in the step of forming a pixel defining layer, the pixel defining layer PDL may be formed on a portion of the circuit layer CL.

In the step of forming a first electrode, the first electrode EL1 may be formed on a portion of the circuit layer CL where the pixel defining layer PDL is not formed.

In the step of forming a light-emitting layer, the light-emitting layer OL may be formed on the first electrode EL1.

In the step of forming a second electrode, the second electrode EL2 may be formed on the light-emitting layer OL. Moreover, the first electrode EL1, the light-emitting layer OL and the second electrode EL2 may be substantially stacked to form a light-emitting diode.

In the step of forming a light-emitting encapsulation layer, the light-emitting encapsulation layer LEL may be formed on the light-emitting diode layer LL.

In the step of forming a color control layer, the color control layer CCL may be formed. Moreover, the step of forming a color control layer may include forming a bank and forming a color control section.

In the step of forming a bank, the bank BNK may be formed on a portion of the light-emitting encapsulation layer LEL.

In the step of forming a color control section, the color control section CCS may be formed on a portion of the light-emitting encapsulation layer LEL where the bank BNK is not formed. The step of forming a color control section may include forming a first color control section, forming a second color control section, and forming a third color control.

In the step of forming a first color control section, the first color control section CCS1 may be formed. In the step of forming a second color control section, the second color control section CCS2 may be formed. In the step of forming a third color control section, the third color control section CCS3 may be formed.

In the step of forming a bottom capping layer, the bottom capping layer BCL may be formed on the color control layer CCL.

In the step of forming a spacer, the spacer SPC may be formed on the bottom capping layer BCL.

In the step of manufacturing a top substrate, the top substrate TS may be formed. Moreover, the step of manufacturing a top substrate may include forming a color filter, forming a low refraction layer, and forming a top capping layer.

In the step of forming a color filter, the plurality of color filters CF may be formed on the top base substrate TBS. Moreover, the step of forming a color filter may include forming a first color filter, forming a second color filter, and forming a third color filter.

In the step of forming a first color filter, the first color filter CF1 may be formed. In the step of forming a second color filter, the second color filter CF2 may be formed. In the step of forming a third color filter, the third color filter CF3 may be formed.

In the step of forming a low refraction layer, the low refraction layer LRL may be formed on the plurality of color filters CF.

In the step of forming a top capping layer, the top capping layer TCL may be formed on the low refraction layer LRL.

In the step of bonding, the filling layer FL may be formed. By way of example, the filling layer FL may be filled between the bottom substrate and the top substrate to bond the bottom substrate with the top substrate.

While embodiments have been described above, one of ordinary skill in the art to which the disclosure pertains shall appreciate that there may be a variety of modifications and permutations of the disclosure without departing from the technical ideas and scopes of the disclosure and that are defined in the appended claims. Moreover, it shall be appreciated that the disclosed embodiments are not intended to restrict the disclosure thereto and that every technical idea within the appended claims and their equivalents is interpreted to be included in the scope of the disclosure.

What is claimed is:

1. A display device comprising:
a lower substrate comprising a light-emitting diode layer, a color control layer and a spacer, the light-emitting diode layer comprising a plurality of light-emitting diodes, the color control layer comprising a bank and a first color control portion, the bank including an opening, the first color control portion disposed in the opening, the spacer disposed on the bank, the first color control portion comprising a quantum dot;
an upper substrate disposed on the lower substrate and comprising a plurality of color filters; and
a filling layer disposed between the lower substrate and the upper substrate and that adheres the lower substrate with the upper substrate, the filling layer having a higher refractive index than a refractive index of the spacer.

2. The display device of claim 1, wherein
the plurality of color filters comprise a first color filter, and
a portion of light emitted from the first color control portion is reflected by the spacer, and
a portion of the reflected light passes through the first color filter and is emitted outside of the display device.

3. The display device of claim 2, wherein
another portion of the light emitted from the first color control portion passes through the spacer, and
the passed light does not emit outside of the display device.

4. The display device of claim 3, wherein
the first color control portion emits light having a first wavelength,
the first color control portion further comprises:
a second color control portion that emits light having a second wavelength different from the first wavelength, the second color control portion adjacent to the first color control portion and spaced apart from the first color control portion by a first distance; and
a third color control portion that emits light having a third wavelength different from the first wavelength and the second wavelength, the third color control portion adjacent to the second color control portion and spaced apart from the second color control portion by a second distance,
a smaller value of the first distance and the second distance is defined as an adjacent distance,
a portion of the bank separated from the first color control portion to the adjacent distance is defined as a first adjacent area, and a portion of the bank separated from the second color control portion to the adjacent distance is defined as a second adjacent area, and a portion of the bank separated from the third color control portion to the adjacent distance is defined as a third adjacent area, and
the spacer is disposed on at least one of the first adjacent area, the second adjacent area and the third adjacent area.

5. The display device of claim 4, wherein
an area of the bank in which the first adjacent area and the second adjacent area overlap each other is defined as a first overlap area, and an area of the bank in which the second adjacent area and the third adjacent area overlap each other is defined as a second overlap area, and
the spacer is disposed on at least one of the first overlap area and the second overlap area.

6. The display device of claim 4, wherein
the first color control portion, the second color control portion and the third color control portion each extend in a selectable direction,
the first color control portion, the second color control portion and the third color control portion are disposed in a direction intersecting the selectable direction, and
the spacer extends in the selectable direction.

7. The display device of claim 4, wherein a distance between the spacer and the upper substrate is greater than or equal to about 0.3 μm and less than or equal to about 2 μm.

8. The display device of claim 4, wherein the spacer has a shape enclosing each of the first color control portion, the second color control portion, and the third color control portion in plan view.

9. The display device of claim 4, wherein
the first color control portion, the second color control portion, and the third color control portion each extend in a selectable direction, and
the spacer comprises:
a first sub-spacer disposed between the first color control portion and the second color control portion in plan view and extending in the selectable direction; and
a second sub-spacer disposed between the second color control portion and the third color control portion in plan view and extending in the selectable direction, the second sub-spacer being spaced apart from the second sub-spacer.

10. The display device of claim 4, wherein
the first color control portion, the second color control portion and the third color control portion each extend in a selectable direction, and
the spacer comprises:
a first sub-spacer is disposed between the first color control portion and the second color control portion in plan view and extending in the selectable direction; and
a second sub-spacer having a shape enclosing the third color control portion in plan view.

11. The display device of claim 4, wherein the spacer comprises a plurality of sub-spacers, each of the plurality of sub-spacers having a substantially circular or substantially oval shape.

12. The display device of claim 11, wherein
a plurality of first sub-spacers among the plurality of sub-spacers are disposed on the first adjacent area,
a plurality of second sub-spacers among the plurality of sub-spacers is disposed on the third adjacent area, and
a number of the plurality of second sub-spacers is greater than a number of the plurality of first sub-spacers.

13. The display device of claim 4, wherein
the refractive index of the spacer is greater than or equal to about 1.3 and less than or equal to about 1.4, and
the refractive index of the filling layer is greater than or equal to about 1.45 and less than or equal to about 1.55.

14. A display device comprising:
a light-emitting diode layer that emits light;
a bank disposed on the light-emitting diode layer and comprising a plurality of partition walls;
a plurality of color control portions, at least one of the plurality of color control portions comprising a quantum dot, each of the plurality of color control portions disposed between the plurality of partition walls;
a spacer comprising a plurality of sub-spacers disposed, respectively, on the plurality of partition walls and having a first refractive index;
a filling layer disposed on the spacer and the plurality of color control portions and having a second refractive index greater than the first refractive index; and
a plurality of color filters disposed on the filling layer.

15. The display device of claim 14, wherein
a portion of light emitted from the plurality of color control portions is reflected by the spacer, and
a portion of the reflected light passes through the plurality of color filters and is emitted outside of the display device.

16. The display device of claim 15, wherein each of the plurality of sub-spacers comprises a portion with a decreasing cross-sectional area away from the bank.

17. The display device of claim 15, wherein a distance between the spacer and the plurality of color filters is greater than or equal to about 0.3 μm and less than or equal to about 2 μm.

18. The display device of claim 15, wherein
each of the plurality of color control portions extends in a selectable direction,
the plurality of color control portions are disposed in a direction intersecting the selectable direction, and
each of the plurality of sub-spacers comprises a portion extending in the selectable direction.

19. The display device of claim 15, wherein each of the plurality of sub-spacers has a shape enclosing at least one of the plurality of color control portions in plan view.

20. The display device of claim 15, wherein each of the plurality of color control portions extends in a selectable direction, and
wherein the plurality of sub-spacers comprise:
a first sub-spacer extending in the selectable direction; and
a second sub-spacer extending in the selectable direction and being spaced apart from the first sub-spacer.

21. A electronic device comprising:
a lower substrate comprising a light-emitting diode layer, a color control layer and a spacer, the light-emitting diode layer comprising a plurality of light-emitting diodes, the color control layer comprising a bank and a first color control portion, the bank including an opening, the first color control portion disposed in the opening, the spacer disposed on the bank, the first color control portion comprising a quantum dot;
an upper substrate disposed on the lower substrate and comprising a plurality of color filters; and
a filling layer disposed between the lower substrate and the upper substrate and that adheres the lower substrate with the upper substrate, the filling layer having a higher refractive index than a refractive index of the spacer.
